(19) United States
(12) Patent Application Publication
(10) Pub. No.: US 2025/0283854 A1
(43) Pub. Date: Sep. 11, 2025

(54) MAGNETIC INSPECTION AND MONITORING DEVICE FOR A PIPE

(71) Applicants: Chevron U.S.A. Inc., San Ramon, CA (US); Advanced Innergy Solutions Ltd, Gloucester (GB)

(72) Inventors: Antonio C.F. Critsinelis, Kingwood, TX (US); Baha Tulu Tanju, Houston, TX (US); Menno van der Horst, Houston, TX (US); Richard McNealy, Houston, TX (US); Sid Mebarkia, Sugar Land, TX (US); Yiannis Constantinides, Katy, TX (US); Austin Harbison, Skelmersdale, Lancashire (GB)

(21) Appl. No.: 18/858,314

(22) PCT Filed: Apr. 21, 2023
(86) PCT No.: PCT/US2023/066092

§ 371 Date: Oct. 19, 2024

Related U.S. Application Data
(60) Provisional application No. 63/363,328, filed on Apr. 21, 2022.

(51) Int. Cl. G01N 27/82; G01B 7/06

(52) U.S. Cl. CPC G01N 27/82; G01B 7/10

(57) ABSTRACT

A pipe inspection device includes a magnetometer for detecting magnetic field measurements associated with a characteristic of a wall of an subsea pipe. The magnetometer can detect environmental magnetic fields as well as magnetic fields generated in response to a magnetic field applied to the pipe. The magnetic field measurements can indicate defects and changes in defects over time in the wall of the pipe caused by erosion or corrosion. Changes in magnetic field measurements over time can provide an indication of changes in pipe wall characteristics. After detecting and storing the magnetic field measurements, the pipe inspection device can be moved to another location on the pipe to gather additional measurements.

### RELATED APPLICATIONS

The present application claims priority to U.S. Provisional Patent Application No. 63/363,328 filed Apr. 21, 2022, the entire content of which is incorporated herein by reference.

### TECHNICAL FIELD

Embodiments of the technology relate generally to measuring the integrity of a pipe using a pipe mounted magnetic sensor.

### BACKGROUND

Pipelines are commonly used to transport fluids, including water, gasses, and petroleum products on land as well as undersea. Pipelines include tubular pipe components that can include straight and bent sections of pipe, as well as sections with more complex geometries such as reducers, expanders, elbow joints, and tee joints. In undersea pipelines that transport hydrocarbons, the pipelines typically include risers which are pipe components engineered to transport fluids vertically between the seafloor and facilities at the water's surface such as drilling or production facilities.

Pipelines typically are manufactured from steel and are subject to wear on their internal and external surfaces from erosion and/or corrosion. Erosion and corrosion can be caused by fluids flowing within the pipeline as well as environmental conditions surrounding the exterior of the pipeline. This wear caused by erosion and corrosion reduces the thickness of the wall of the pipeline over time. In the production of hydrocarbons, pipelines are critical infrastructure components. Therefore, the ability to regularly monitor and inspect the integrity of pipelines improves the process of producing hydrocarbons and reduces safety hazards. However, inspecting and monitoring pipelines to assess wear is an expensive and challenging task.

In order to maintain the integrity of pipelines, a variety of techniques are available to monitor and inspect sections of the pipe systems and detect internal wear of the pipe sections. One approach uses an intelligent pipeline inspection gauge (“PIG”), also referred to as an in-line inspection tool, that travels along the inside of the piping system and uses sensors, such as ultrasonic sensors or magnetic flux leakage sensors, to measure the wall thickness of the pipeline. The PIG can travel the length of the pipeline mapping the wall thickness of the pipeline so that areas of wear can be identified. Usually, inspections with a PIG are required to be performed with a frequency that will enable monitoring and tracking the integrity of the pipeline over an extended time. However, using a PIG to inspect a pipeline has several disadvantages. First, placing the PIG within the pipeline for an inspection interrupts the production process and typically requires many months of advance planning. This interruption of production and the use of the PIG device results in substantial expenses. There can be technical challenges associated with deploying the PIG device at substantial undersea depths where hydrostatic pressure and temperatures are extreme. Additionally, the PIG device can become stuck in the pipeline creating additional engineering challenges and associated risks.

In light of the foregoing disadvantages, the PIG device cannot be used frequently to inspect a pipeline. Given the limited ability to regularly inspect the pipeline with a PIG device, operators use conservative predictions of the service lifetime for the pipeline resulting in replacement of pipeline components well before excessive wear can occur. However, replacing pipeline components prematurely adds to the expense of the hydrocarbon production process.

Aside from a PIG device, other approaches to inspecting pipelines have their own limitations. For example, in the context of undersea pipelines, devices have been used to inspect a pipeline from the exterior of the pipeline. However, such devices can be difficult to operate and can require that they be tethered to other equipment at the water's surface.

Accordingly, there is a need for an improved technique for screening and detecting defects or anomalies in pipeline walls with non-intrusive devices and methods. Specifically, a sensing technique that can be placed at strategic locations, which are vulnerable to corrosion and erosion, to collect data regarding the characteristics of the pipe wall with greater ease and greater frequency would be beneficial. Additionally, a technique that would allow for monitoring a pipe over a period of time would be useful. Such a technique could identify areas of unexpectedly rapid deterioration in the pipeline so that they can be addressed at the right timing (not too late, not too early). Additionally, such a technique could provide a more accurate assessment of the pipeline potentially extending the service lifetime of pipeline components. Moreover, this non-invasive, less expensive, and less risky screening solution can either eliminate the use of PIG in line inspection or reduce the frequency required to monitor and track the integrity of pipelines.

### SUMMARY

The present disclosure is directed to apparatus and methods for inspecting and monitoring pipe. In one example embodiment, the disclosure is directed to a clamping inspection device for measuring a characteristic of a wall of a pipe. The clamping inspection device can include: (i) a first jaw that engages a first side of the pipe; (ii) a second jaw that engages a second side of the pipe; (iii) a securing means for securing the first jaw and the second jaw to the pipe; (iv) a sensor coupled to at least one of the first jaw and the second jaw, the sensor comprising a magnetometer that detects magnetic field measurements associated with the characteristic of the wall of the pipe; and (v) a controller coupled to the clamping inspection device, the controller comprising a power source and data storage device, wherein the data storage device receives the magnetic field measurements from the sensor via a communication link.

The foregoing clamping inspection device can include one or more of the following features. The sensor can further comprise a coil that receives a power signal from the power source and generates an applied magnetic field. The magnetic field measurements can be response magnetic field measurements generated in response to the applied magnetic field. The controller can further comprise a wireless communication link that transmits the magnetic field measurements to a remote data collection device, wherein the wireless communication link communicates the magnetic field measurements by one of optical signals, radio signals, acoustic signals, and magnetic pulse signals. The remote collection device can be onboard one of: a remotely operated vehicle, an autonomous underwater vehicle, equipment located undersea, and a platform at a water's surface. The controller can comprise a processor that analyzes the magnetic field measurements and determines a wall thickness indicator. The processor can calibrate the clamping inspection device using at least one of environmental magnetic field measurements, a geometry of the pipe, and a magnetic permeability of material of the pipe. The magnetic field measurements associated with the characteristic of the wall of the pipe can be compared to prior magnetic field measurements to determine a change in the characteristic of the wall of the pipe.

Another example embodiment is directed to a method for measuring a characteristic of a wall of a pipe using a pipe inspection device, wherein the method includes: (i) installing the pipe inspection device at a first location on the pipe; (ii) detecting, by a magnetometer, magnetic field measurements associated with the characteristic of the wall of the pipe, the magnetometer located within a sensor of the pipe inspection device; and (iii) transmitting, by a controller via a wireless communication link, the magnetic field measurements to a remote data collection device.

The foregoing method can include one or more of the following features. The magnetic field measurements can be response magnetic field measurements generated in response to an applied magnetic field, the applied magnetic field generated by a coil of the sensor that receives a power signal from a power source of the controller. The wireless communication link can transmit the magnetic field measurements by one of optical signals, radio signals, acoustic signals, and magnetic pulse signals. The remote data collection device can be onboard one of: a remotely operated vehicle, an autonomous underwater vehicle, equipment located undersea, and a platform at the water's surface. The method can further comprise: (iv) calculating, by a processor, a wall thickness indicator from the magnetic field measurements; and (v) transmitting, by the controller, the wall thickness indicator from the data storage device to the remote data collection device. The method can further comprise: calibrating the pipe inspection device using at least one of environmental magnetic field measurements, a geometry of the pipe, and a magnetic permeability of material of the pipe. The magnetic field measurements associated with the characteristic of the wall of the pipe can be compared to prior magnetic field measurements to determine a change in the characteristic of the wall of the pipe. The method can further comprise: (iv) disengaging, using a remotely operated vehicle, the pipe inspection device from the pipe at the first location; (v) installing the pipe inspection device at a second location on the pipe; (vi) detecting, by the magnetometer, magnetic field measurements associated with the wall thickness of the pipe at the second location; and (vii) transmitting, by the controller, the magnetic field measurements from the second location to the remote data collection device.

Yet another example embodiment is directed to an inspection device for measuring a characteristic of a wall of a pipe. The inspection device can include: (i) a fastener that secures the inspection device to the pipe; (ii) a sensor comprising a magnetometer that detects magnetic field measurements associated with the characteristic of the wall of the pipe; and (iii) a controller comprising a power source and a data storage device, wherein the data storage device receives the magnetic field measurements from the sensor via a communication link.

The foregoing inspection device can include one or more of the following features. The sensor can further comprise a coil that receives a power signal from the power source and generates an applied magnetic field. The magnetic field measurements can be response magnetic field measurements generated in response to the applied magnetic field. The controller can further comprise a wireless communication link that transmits the magnetic field measurements to a remote data collection device, wherein the wireless communication link communicates the magnetic field measurements by one of optical signals, radio signals, acoustic signals, and magnetic pulse signals. The remote collection device can be onboard one of: a remotely operated vehicle, an autonomous underwater vehicle, equipment located undersea, and a platform at a water's surface. The controller can comprise a processor that analyzes the magnetic field measurements and determines a wall thickness indicator. The processor can calibrate the clamping inspection device using at least one of environmental magnetic field measurements, a geometry of the pipe, and a magnetic permeability of material of the pipe. The magnetic field measurements associated with the characteristic of the wall of the pipe can be compared to prior magnetic field measurements to determine a change in the characteristic of the wall of the pipe.

The foregoing embodiments are non-limiting examples and other aspects and embodiments will be described herein. The foregoing summary is provided to introduce various concepts in a simplified form that are further described below in the detailed description. This summary is not intended to identify required or essential features of the claimed subject matter nor is the summary intended to limit the scope of the claimed subject matter.

### BRIEF DESCRIPTION OF THE DRAWINGS

The accompanying drawings illustrate only example embodiments of a pipe inspection and monitoring device and method and therefore are not to be considered limiting of the scope of this disclosure. The principles illustrated in the example embodiments of the drawings can be applied to alternate methods and apparatus. Additionally, the elements and features shown in the drawings are not necessarily to scale, emphasis instead being placed upon clearly illustrating the principles of the example embodiments. Certain dimensions or positions may be exaggerated to help visually convey such principles. In the drawings, the same reference numerals used in different embodiments designate like or corresponding, but not necessarily identical, elements.

FIG. 1 illustrates a clamping inspection device attached to the exterior of a pipe in accordance with an example embodiment of the disclosure.

FIG. 2 illustrates the other side of the clamping inspection device of FIG. 1 attached to the exterior of the pipe in accordance with an example embodiment of the disclosure.

FIG. 3 illustrates an undersea pipeline with multiple pipe inspection devices attached to the exterior of the pipeline in accordance with an example embodiment of the disclosure.

FIG. 4 is a flowchart illustrating a method of using a pipe inspection device in accordance with an example embodiment of the disclosure.

FIG. 5 illustrates the components of the sensor housing and the data storage housing in accordance with an example embodiment of the disclosure.

FIGS. 6A and 6B illustrate another example of a clamping inspection device attached to the exterior of a pipe in accordance with an example embodiment of the disclosure.

FIG. 7 illustrates components of a controller and a sensor of a clamping inspection device in accordance with an example embodiment of the disclosure.

FIGS. 8A and 8B illustrate components of a sensor of a clamping inspection device in accordance with an example embodiment of the disclosure.

FIG. 9 is a flowchart illustrating a method of using a pipe inspection device in accordance with an example embodiment of the disclosure.

FIGS. 10, 11, and 12 illustrate examples of magnetic field data that can be collected with a pipe inspection device in accordance with an example embodiment of the disclosure.

FIG. 13 illustrates another example of a pipe inspection device attached to the exterior of a pipe in accordance with an example embodiment of the disclosure.

FIG. 14 illustrates another example of a pipe inspection device attached to the exterior of a pipe in accordance with an example embodiment of the disclosure.

### DETAILED DESCRIPTION OF EXAMPLE EMBODIMENTS

The example embodiments discussed herein are directed to apparatus and methods for a pipe inspection device for detecting wear in the wall of a pipeline. The example apparatus and methods described herein are particularly beneficial in the oil and gas industry where fluids are often transported through lengthy pipelines. The examples described herein improve upon prior approaches to detecting wall thickness wear of a pipeline because they can be deployed more easily in remote locations, including remote undersea locations. While examples of devices used to inspect undersea pipelines are described herein, the devices and methods described herein also can be applied to pipelines located on land. Additionally, the example devices described herein can be deployed for extended periods of time for monitoring a pipe. As will be described, the approaches disclosed herein address one or more of the challenges associated with the costs and complexity of assessing wall thickness wear of a pipeline. Obtaining an accurate assessment of wear within a pipeline is beneficial in that service interruptions and unplanned downtime for the pipeline can be reduced. Additionally, improved wear assessment reduces premature and unnecessary replacement of pipe sections in which wear is not yet a problem. The foregoing benefits will be evident from the following description of example embodiments for a clamping inspection device.

In the following paragraphs, particular embodiments will be described in further detail by way of example with reference to the drawings. In the description, well-known components, methods, and/or processing techniques are omitted or briefly described. Furthermore, reference to various feature(s) of the embodiments is not to suggest that all embodiments must include the referenced feature(s).

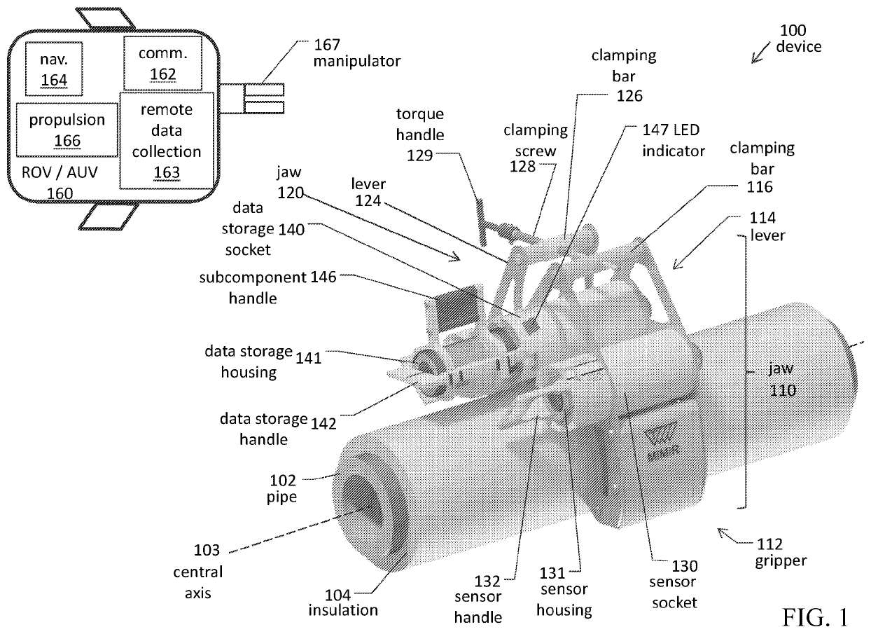

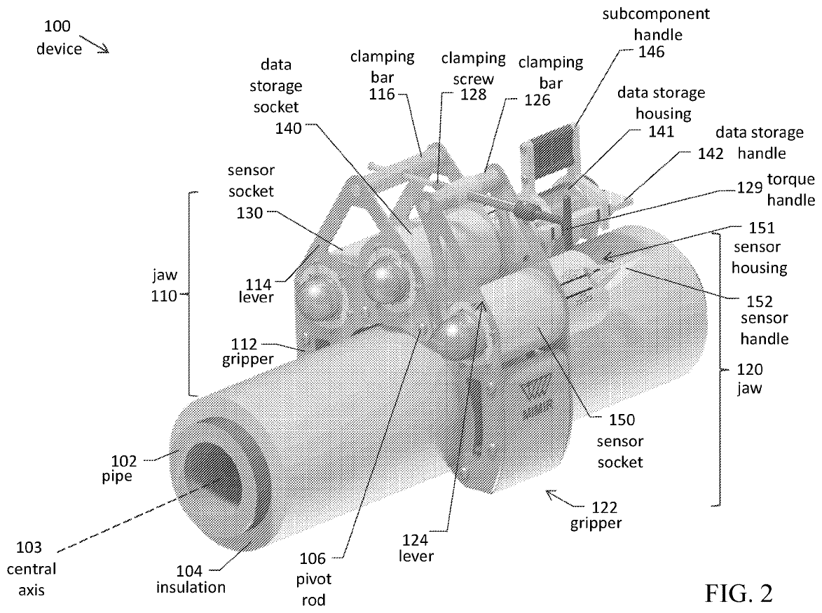

FIGS. 1 and 2 illustrate one type of pipe inspection device that clamps onto the exterior of a pipe. Other example embodiments of the pipe inspection device can be attached to the pipe using other means, such as straps, magnetic attachment, or adhesive attachment. In such other embodiments, a mount portion of the pipe inspection device is attached to the pipe and supports other components such as a sensor housing and data storage housing. In the case where straps are used, a diver can secure the mount to the exterior of the pipe by wrapping the straps around the pipe. In other cases, the mount can include one or more magnets or an adhesive material that secures the mount of the inspection device to the exterior of the pipe. In yet other embodiments, the housing of the pipe inspection device is coupled directly to the pipe without a mount and using any of a variety of securing means. Instead of a mount, the pipe inspection device is coupled directly to the pipe with a securing means or fastener, such as a strap, clamp, or magnetic or adhesive attachment mechanism, that secures the pipe inspection device to the pipe.

Referring to the clamping type of attachment, FIGS. 1 and 2 illustrate opposite sides of a clamping inspection device attached to a section of pipe of a pipeline in accordance with example embodiments of the disclosure. It should be understood that the clamping inspection device illustrated in FIGS. 1 and 2 is an example and that in alternate embodiments the clamping inspection device can take alternate forms. In alternate embodiments, certain of the features of the clamping inspection device of FIGS. 1 and 2 may be modified or omitted. Furthermore, in alternate embodiments additional features may be added to the clamping inspection device.

In FIGS. 1 and 2, an example clamping inspection device 100 is shown attached to a section of pipe 102 that makes up part of a larger undersea pipeline. The pipe 102 has a central axis of symmetry 103 passing along the longitudinal center of the pipe. The pipe 102 is typically made of steel and, therefore, has an inherent magnetic field that can be detected with a magnetometer. Alternatively, one or more magnets or electromagnets can be placed on, within, or proximate to the pipe to induce a magnetic field in the wall of the pipe that can be measured by the clamping inspection device. In the example of FIGS. 1 and 2, the pipe 102 has a layer of insulation 104 surrounding the outer surface of the pipe 102 to protect the pipe and the contents flowing through the pipe from the cold temperatures at deep sea depths. In the following description, the pipe and the insulation will be referred to together generally as the pipe 102. It should be understood that the clamping inspection device can be attached to a variety of pipes, including those without insulation, and a variety of pipe shapes and configurations. When used herein, the term “pipe” should be interpreted broadly and can encompass any pipe or related pipe components, including a pipe fitting, a weld, a flange, a pipe elbow, a pipe tee, a connector, and a valve. Similarly, references to pipe wall thickness and wear should be interpreted broadly to encompass any defects or anomalies associated with the pipe wall that can be detected with the magnetic field measurements, including cracks, pits, erosion, and changes in the thickness of the wall of the pipe.

In the example of FIG. 1, the clamping inspection device 100 has been placed on the pipe 102 using an undersea remotely operated vehicle (ROV) 160. It should be understood that in alternate embodiments, ROV 160 can be replaced by an autonomous undersea vehicle (AUV). The ROV 160 is one example of a piece of equipment that can be used to attach the clamping inspection device 100 to the pipe 102, as well as remove the device from the pipe. In other examples, the clamping inspection device 100 can be attached to and removed from the pipe using other undersea equipment or the device can be attached to the pipe before the pipe is positioned undersea. The example ROV 160 includes a communication system 162 that allows data signals, including control commands, to be communicated between the ROV 160 and other equipment located at the surface or undersea. The communication system 162 can support communications of a variety of types, including optical signals, radio signals, and audio signals. A remote data collection device 163 onboard the ROV can store data collected from the clamping inspection device 100 as will be described further below. The ROV 160 also includes a navigation system 164 used to direct the ROV 160 in the desired direction and a propulsion system 166 that drives the ROV 160 towards the desired destination. Lastly, the ROV 160 includes a manipulator 167 that can be controlled with the received control commands and that can be used to actuate other devices, including lifting and turning other devices. In the example of FIG. 1, the ROV's manipulator 167 can be used to place the clamping inspection device 100 on the pipe 102, and to manipulate clamping bars and handles on the clamping inspection device 100.

The clamping inspection device 100 includes a first jaw 110 and a second jaw 120 that attach to alternate sides of the pipe 102. The first jaw 110 comprises a first gripper 112 that contacts the pipe 102. The first jaw 110 further comprises a first lever 114 that extends from the first gripper 112 to a first clamping bar 116. The first clamping bar 116 extends parallel to the central axis 103 of the pipe 102. Similarly, the second jaw 120 comprises a second gripper 122 that contacts the pipe 102 on a side opposite the first gripper 112. The second jaw further comprises a second lever 124 that extends from the second gripper 122 to a second clamping bar 126. The second clamping bar 126 extends parallel to the central axis 103 of the pipe 102. Together, the first and second clamping bars 116 and 126 provide a feature for grasping the clamping inspection device, using the ROV 160 or other equipment, so that the clamping inspection device can be moved and placed at a desired location.

The first jaw 110 and second jaw 120 are attached by and rotate about a pivot rod 106 that is parallel to the central axis 103 when the clamping inspection device is attached to the pipe 102. Although not visible in FIGS. 1 and 2, the first and second jaws can also be attached to a spring that biases the first gripper 112 and the second gripper 122 towards each other for securing the clamping inspection device to the pipe 102. Once the clamping inspection device 100 is placed on pipe 102 with the first gripper 112 and second gripper 122 contacting opposite sides of the pipe 102, a clamping screw 128 can be rotated to push the clamping bars 116 and 126 apart, thereby tightening the clamping inspection device 100 onto the pipe 102. Alternatively, if removing the clamping inspection device 100 from the pipe 102, the clamping screw 128 can be rotated in the opposite direction thereby pulling the clamping bars 116 and 126 together and loosening the clamping inspection device 100 from the pipe 102. Rotating the torque handle 129, using the ROV's manipulator 167 for example, allows one to tighten or loosen of the clamping screw 128.

The example clamping inspection device 100 illustrated in FIGS. 1 and 2 includes sensor sockets 130 and 150 and data storage socket 140. The sensor sockets 130 and 150 receive sensor housings 131 and 151, respectively. Similarly, the data storage socket 140 receives data storage housing 141. A sensor socket and sensor housing can be referred to as a sensor socket-housing assembly and a data storage socket and data storage housing can be referred to as a data storage socket-housing assembly. It should be understood that alternate embodiments of the clamping inspection device may have only a single sensor socket-housing assembly or more than two sensor socket-housing assemblies. Similarly, more than one data storage socket-housing assembly is also possible. The example clamping inspection device has the data storage socket-housing assembly positioned between the first and second jaws 110, 120 and a sensor socket-housing assembly located on each respective jaw. In alternate embodiments, the data storage socket-housing assembly and sensor socket-housing assembly can be located at other positions on the clamping inspection device. For example, in certain embodiments, it may be advantageous to have one or more sensor housings extending around a greater portion of the circumference of the pipe than illustrated in FIGS. 1 and 2 to obtain more accurate or complete data regarding the wall thickness of the pipe. Sensor housings located around the circumference of the pipe can provide a more complete assessment of the pipe wall about the entire circumference of the pipe.

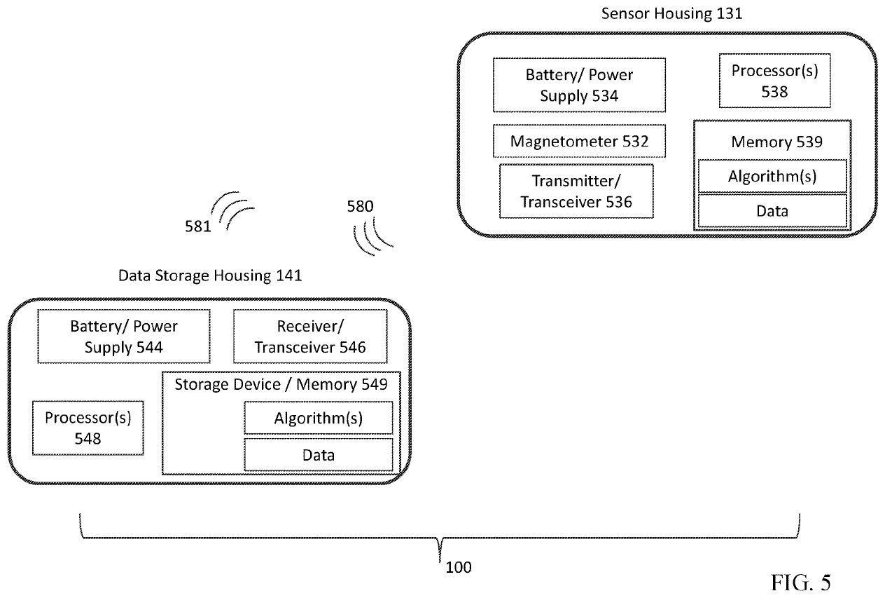

The sensor housings 131 and 151 can be vessels designed to withstand the effects of hydrostatic pressure encountered at great undersea depths. The sensor housings 131 and 151 can have a cylindrical shape that is sealed to withstand large hydrostatic pressures. As illustrated in greater detail in FIG. 5 with the example sensor housing 131, the sensor housings 131 and 151 can each contain one or more magnetometers 532 that detect magnetic field measurements from the steel of the pipe 102. The magnetic field measurements can provide an indication of one or more characteristics of the pipe wall, such as wall thickness, cracks that may be present in the wall, or a certain type of corrosion of the pipe wall. For example, changes in magnetic field measurements over time can provide an indication of a change in pipe wall thickness or a change in the size of a crack in the pipe wall. The magnetometer is not in direct contact with the pipe because it is contained entirely within the sealed sensor housing from which it is able to make measurements.

Additionally, the sensor housings 131 and 151 can each contain a memory 539 that stores magnetic field measurements, a battery 534 for power, and a sensor transmitter 536 that transmits the detected magnetic field measurements to the data storage housing 141. The battery can take a variety of forms and in other embodiments can be other types of power sources, such as a fuel cell, a thermoelectric generator, or a kinetic power source that relies upon motion such as the motion of the sea to drive a turbine. Advances in the miniaturization and power consumption of electronic components as well as the capacity of batteries enable sensors to be deployed and to operate for years before requiring maintenance or replacement. The sensor housings can also contain the appropriate cables and interfaces for supplying power from the power source to the sensor and communication components. Preferably, the sensor transmitter communicates the magnetic field measurements via a wireless communication method, such as optical signals, radio signals, acoustic signals, magnetic pulse signals, or MQS. Accordingly, the magnetometer and sensor transmitter do not require any wires extending outside the sealed sensor housing. Eliminating wires that might extend from the sensor housings 131 and 151 eliminates challenges presented by large hydrostatic pressures and facilitates the insertion and removal of the sensor housings 131 and 151 with respect to the sensor sockets 130 and 150.

The magnetometer within the sensor housing can be used in a variety of approaches for inspecting and monitoring a pipeline. As one example, the magnetometer can make passive measurements of the magnetic field about the pipeline and changes in the magnetic field can provide an indication of changes in the characteristics (e.g., wall thickness, cracks, pits, corrosion) of the wall of the pipeline. In some cases, the data collected from the passive measurements can be filtered to adjust for one or more of environmental factors, the Earth's magnetic field, or the decay of the pipelines remnant magnetic field. In other embodiments, the magnetometer can be used in an active approach to gathering magnetic field measurements. For example, the pipeline wall can be pulsed with an applied electromagnetic field and the response of the magnetic field of the pipeline wall to the pulse can be measured with the magnetometer. In another example of an active approach, a magnet that applies a magnetic field can be placed on, within, or proximate to the pipe that is being monitored. The magnet can be used to induce or enhance a magnetic field in the wall of the pipe that can be measured by the magnetometer. Such an induced or enhanced magnetic field can assist in obtaining more useful and/or accurate measurements with the magnetometer in the sensor housing. In some cases, magnetic field measurements from multiple sensors of the monitoring device that are disposed about the circumference of the pipe can be compared to analyze the pipeline's magnetic field. As yet another example, magnetic field measurements from sensors located on different inspection devices located along a length of a pipeline can be compared to analyze the pipeline's magnetic field.

It should be understood that various types of magnetometers can be implemented in the sensor housing, including AMR, GMR, TMR, and flux gate magnetic sensors. An advantage of the inspection devices described herein is that the sensor socket-housing assembly can facilitate use of a variety of sensors. For example, in some embodiments other types of sensors such as ultrasonic or X-ray sensors could be used in place of or in conjunction with magnetic sensors to inspect or monitor a section of pipeline.

Optionally, the sensor housings 131 and 151 can include a processor 538 that executes algorithms stored in memory to analyze the magnetic field measurements and generate an indication of wall thickness for the pipe. Alternatively, the magnetic field measurements can provide an indication of defects in the pipe wall, such as cracks, particular types of corrosion, or other characteristics of the pipe wall. In connection with analyzing the magnetic field measurements, the software can also make adjustments to the data for the Earth's magnetic field or for other factors. In certain examples, the software executing on the processor can analyze magnetic field measurements gathered over time to determine changes in the magnetic field measurements over time that are associated with changes in one or more characteristics of the pipe, such as wall thickness or anomalies in the pipe wall such as cracks, pits, or corrosion. One advantage of including the processor and software is that it can reduce the volume of data that is communicated such that instead of communicating all of the detected measurements, the clamping inspection device is only required to transmit a subset of data, or a filtered set of data, or only an indication of wall thickness. Such an approach can reduce the power requirements for the batteries on the clamping inspection device.

Similarly, the data storage housing 141 can be a sealed vessel designed to withstand significant hydrostatic pressures encountered at undersea depths. As one example, the data storage housing can have a cylindrical shape. As illustrated in greater detail in FIG. 5, the data storage housing 141 can contain one or more data storage devices 549, a data storage receiver 546, and a battery for power 544. Preferably, the data storage receiver communicates with the sensor housing(s) via a wireless communication method as indicated by signals 580, such as optical signals (e.g., using LED indicator 147 shown in FIG. 1), radio signals, acoustic signals, magnetic pulse signals, or magneto-quasistatic signals, as described in U.S. Patent Application Publication No. US20210135769, which is incorporated by reference herein in its entirety. As with the sensor housing, the components of the data storage housing 141 do not require any wires that extend outside of the housing. Eliminating wires that might extend from the data storage housing 141 eliminates challenges presented by large hydrostatic pressures and facilitates the insertion and removal of the data storage housing 141 with respect to the data storage socket 140.

As with the sensor housing, the data storage housing 141 can include an optional processor 548 with algorithms for analyzing magnetic field measurements. Similarly, the algorithms executing on the processor 548 can make adjustments to the data, can generate an indication of wall thickness for the pipe, and can track wall thickness changes over time based on changes in the magnetic field measurements. In certain embodiments, it may be advantageous to include the processor and software in the data storage housing 141 instead of the sensor housing(s).

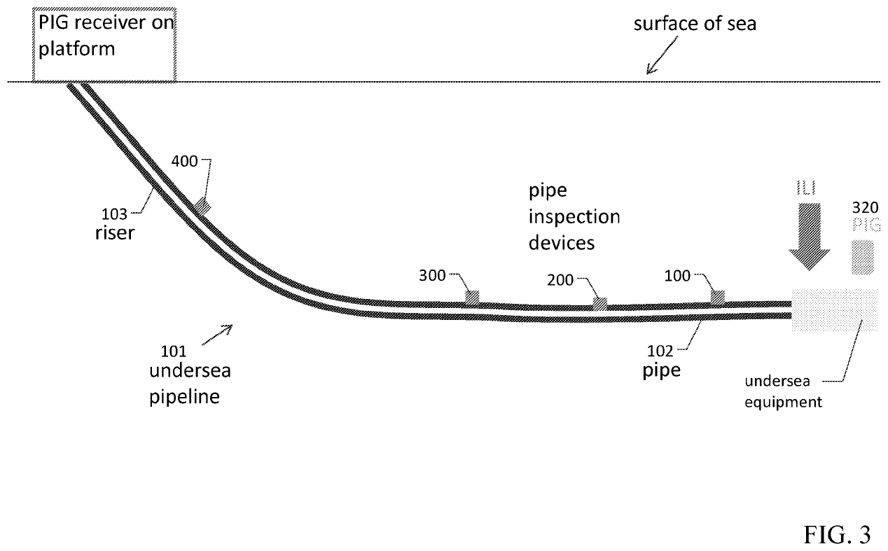

In certain embodiments, the data storage housing 141 can also include an optional data storage transmitter for communicating data associated with the magnetic field measurements to a remote data collection device. In certain examples, the data storage receiver and transmitter can be a combined transceiver 546. As with the data storage receiver, the data storage transmitter can communicate data associated with the magnetic field measurements using a wireless communication method, as indicated by signals 581, such as optical signals, radio signals, acoustic signals, magnetic pulse signals, or MQS. The remote data collection device can be located on the AUV/ROV 160 or can be located at other equipment located undersea or on a platform at the water's surface as illustrated in FIG. 3 described below. As one alternate example, the sensor housing can be located on one clamping device and the data storage housing can be located on another clamping device. In certain example embodiments, clamping inspection devices can communicate among one another forming a communication network through which magnetic field measurements as well as other information can be transmitted. As illustrated in FIG. 3, several clamping inspection devices can be installed along a pipeline. A data storage transceiver onboard a first clamping inspection device can transmit measurements to a data storage transceiver onboard a second clamping inspection device located along the pipeline and such transmissions can continue using other clamping inspection devices until the measurements are received at an endpoint at a platform or at undersea equipment where the data can be further analyzed. The data collected from the magnetic field measurements can be further analyzed and logged so that the status of the wall thickness for the pipe can be tracked over time and more accurate decisions can be made about when to replace pipe sections of the pipeline.

In yet another example embodiment, the data storage housing can be removed from the inspection device and can be included in a separate device, such a ROV or AUV that passes in proximity to the sensor housings on the pipe inspection device. When the ROV or AUV passes in proximity to the sensor housings on the pipe inspection device that is mounted on a pipe, the data storage housing can collect the measured magnetic data via wireless signals (e.g., radio, optical, acoustic, or magnetic signals) from the sensor housings. In yet another variation of this embodiment, the data storage housing also can supply power to the sensor housing, e.g., via an induction coil, to power the magnetometer of the sensor housing and to collect the magnetic measurement data.

As referenced previously, the sensor sockets 130 and 150 each provide a receptacle into which sensor housings 131 and 151 can be respectively inserted and locked into position. As illustrated in FIGS. 1 and 2, sensor housing 131 has an attached sensor handle 132 that extends from one end of the sensor housing 131. The sensor handle 132 facilitates rotating the sensor housing 131 so that it can be locked into place in the sensor socket 130. As one example, the manipulator 167 of the ROV 160 can be used to actuate the sensor handle 132 for installing the sensor housing 131 into the sensor socket 130 and for removing the sensor housing 131 from the sensor socket 130. The sensor socket 130 can include a slot that receives a pin extending from the sensor housing 131 and that locks the sensor housing 131 in place in the sensor socket 130 when the sensor housing 131 is inserted into and rotated within the sensor socket 130. The turn-and-lock mechanism is simply one example and it should be understood that in other embodiments other mechanisms, such as a snap-fit mechanism, can be used to secure the sensor housing 131 to the sensor socket 130.

Sensor housing 151 has a similar sensor handle 152 and can be installed and removed in a manner similar to sensor housing 131. The ability to easily install and remove the sensor housings 131, 151 while leaving clamping inspection device 100 in place on the pipe is advantageous when the clamping inspection device is located undersea. Easy installation and removal of the sensor housings 131, 151 allows the sensor housings to be replaced when batteries lose power or if the sensor is malfunctioning.

Similar to the sensor handles 132, 152, the data storage housing 141 has a data storage handle 142 extending from one end of the data storage housing 141. The data storage handle 142 allows for easy insertion and removal of the data storage housing 141 in a manner similar to that of the sensor housings. As one example, the manipulator 167 of the ROV 160 can be used to insert and remove the data storage housing 141 with respect to the data storage socket 140. Optionally, the data storage housing 141 can also have a subcomponent handle 146 attached to a portion of the data storage housing 141 as illustrated in FIGS. 1 and 2. The subcomponent handle 146 allows for easy removal of a subcomponent of the data storage housing while leaving the remainder of the data storage housing 141 in the data storage socket 140. The portion of the data storage housing removable with the subcomponent handle 146 can include a subcomponent storage device that includes a copy of the data or a portion of the data from the data storage device that remains with the remainder of the data storage housing in the data storage socket. With this optional subcomponent arrangement, the subcomponent of the data storage housing can be easily retrieved when gathering data from the clamping inspection device and another data storage subcomponent can be inserted in its place.

The components of the clamping inspection device can be made from a variety of materials. In certain examples, components such as the grippers 112, 122, the levers 114, 124, the sensor and data storage housings, and the sensor and data storage sockets can be made from materials that are not ferromagnetic so as to minimize interference with the measurements of the magnetometer. For example, materials such as titanium and polymers can be used for some or all of these components.

Referring now to FIG. 3, an undersea pipeline 101 is illustrated to which clamping inspection device 100 is attached, as well as additional clamping inspection devices 200, 300, and 400. While pipe inspection devices of the clamping type illustrated in FIGS. 1 and 2 are referenced in connection with FIG. 3, it should be understood that pipe inspection devices with other attachment means could be used as alternatives. Pipeline 101 consists of multiple sections of pipe, including previously described pipe 102, as well as riser 103. As illustrated in FIG. 3, clamping inspection devices can be placed at various locations along the pipeline 101. As described previously, in certain example embodiments, multiple clamping inspection devices placed along a pipeline can communicate between each device for purposes of transferring measurement data, operating commands, or other information. As also referenced previously, clamping devices can have varying equipment, such as one clamping device that includes a sensor housing which communicates with a data storage housing located on a different clamping device. Furthermore, given the previously described advantages of the clamping inspection devices, the devices can be easily moved to other locations along the pipeline 101 so that wall thickness data can be gathered from multiple locations over time. The clamping inspection devices also can be used in conjunction with other inspection equipment. As one example, FIG. 3 illustrates a PIG device 320 that can be inserted into the pipeline as part of an in-line inspection (“ILI”) operation at a location of undersea equipment. The PIG device 320 can be inserted at one end of the pipeline 101 and can travel along the pipeline until reaching a PIG receiver located on a platform as the surface of the sea.

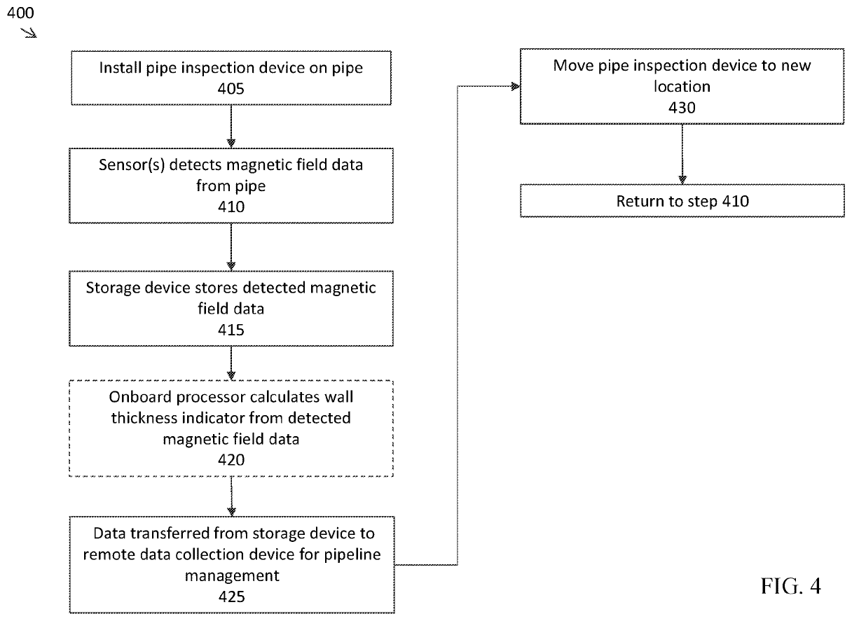

Referring now to FIG. 4, an example method 400 for using a pipe inspection device for measuring wall thickness of a pipe is illustrated. It should be understood that method 400 is a non-limiting example and in alternate embodiments certain steps of method 400 may be modified, combined, performed in parallel, or omitted.

Beginning with operation 405, a clamping inspection device is installed on a section of pipe in a pipeline. The clamping inspection device can be installed using the ROV 160 or using other equipment. As described previously in connection with FIGS. 1 and 2, the clamping inspection device can be installed on the pipe by placing the first jaw and second jaw on opposite sides of the pipe. A spring can bias the jaws to close against the sides of the pipe and a clamping screw can secure the device to the pipe. The magnetometers and other equipment in the sensor housings and the data storage housing can be powered on before the clamping inspection device is submerged or at the time the clamping inspection device is attached to the pipe. For example, the ROV 160 can activate the sensing equipment once the clamping inspection device is attached to the pipe.

It should be understood that in alternative embodiments, operation 405 can involve attaching a pipe inspection device to the pipe using attachment mechanisms other than the clamping type of attachment mechanism. For example, if the pipe inspection device has straps, a diver can secure the pipe inspection device to the pipe by wrapping the straps around the pipe. Straps can be secured around the pipe with any of a variety of mechanisms, including buckles, zippers, snaps, and detents. Similarly, the sensor housing and the data housing can be attached to the inspection device by a variety of mechanisms, including sliding onto straps, snapping to straps, or attaching to buckles. In other embodiments, the pipe inspection device can include a magnet or an adhesive material that secures the device to the pipe.

Once the sensing equipment of the inspection device is activated, the magnetometers can detect magnetic field measurements from the walls of the pipe in operation 410. The measurements can be gathered at predetermined intervals over a certain period of time. As one example, the clamping inspection device can remain on the pipe for many months gathering data periodically to determine whether the wall thickness is changing over time.

When magnetic field data is detected by the magnetometer, a sensor transmitter can communicate the data to a data storage device in the data storage housing, as referenced in operation 415. The data can be communicated at the time it is collected or at some other interval. As explained previously, these communications can be via optical signals, radio signals, audio signals, or magnetic pulse signals.

Operation 420 is an optional step for those examples in which a processor is included in the data storage housing. Software executing on the processor can filter the data as needed and, in certain cases, determine a wall thickness indicator. In embodiments where a processor is included in the sensor housing, data processing can take place before the measured data is communicated to the data storage device.

In operation 425, data is transferred from the data storage device in the data storage housing so that the data can be used in maintaining the pipeline. The data transfer can occur in a variety of ways. As one example, the ROV 160 or another piece of equipment can navigate to the clamping inspection device and gather the data from the clamping inspection device. In one case, the ROV can remove the data storage housing from the data storage socket on the clamping inspection device and return the data storage housing to a platform at the surface where the magnetic field measurements can be further analyzed and used in managing the pipeline. As an alternative to removing the entire data storage housing, the ROV can remove a subcomponent of the data storage housing as described previously in connection with the subcomponent handle illustrated in FIGS. 1 and 2. When the ROV removes the data storage housing or the data storage subcomponent from the clamping inspection device, it can also insert a replacement data storage housing for gathering future measurements. In addition to replacing the data storage housing, the ROV also can replace one or more sensor housings as needed if, for example, if the battery life of the sensor housing is depleted.

As another alternative, the ROV can gather the measurement data from the data storage housing without removing the data storage housing. In other words, when in proximity to the clamping inspection device, the ROV can receive wireless communications from the data storage housing providing a copy of the measurement data that can be stored in a remote data collection device onboard the ROV. The ROV can return to the surface with the copy of the measurement data for further use in managing the pipeline.

In some cases, wall thickness data may be needed from another location along the pipeline. As illustrated in operation 430, the ROV can remove the clamping inspection device from the first location on the pipeline and place it in a second location on the pipeline. As described previously in connection with FIGS. 1 and 2, the ROV can remove the clamping inspection device from the pipe by turning the clamping screw to loosen the device and then engaging the clamping bars towards each other to move the grippers away from the sides of the pipe. The ROV can use the clamping bars to carry the clamping inspection device to another location along the pipeline where it is secured for collecting additional magnetic field measurements. After the measurement data is collected by the ROV or after the ROV moves the clamping inspection device to a new location along the pipeline, method 400 can return to operation 410 wherein the magnetometers continue to make measurements at a desired interval.

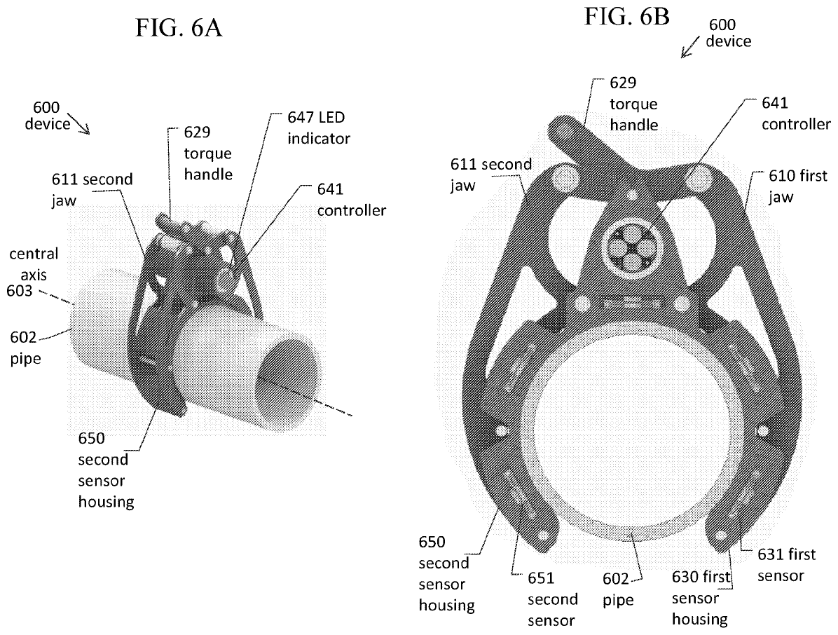

Referring now to FIGS. 6A and 6B, another example of a pipe inspection device that clamps to a pipe is illustrated. As illustrated in FIGS. 6A and 6B, a pipe inspection device 600 is shown attached to a section of undersea pipe 602 that can be part of a larger undersea pipeline. The pipe 602 has a central axis of symmetry 603 passing along the longitudinal center of the pipe 602. The pipe 602 is typically made of a metallic material, such as steel, that may have an inherent magnetic field. The pipe inspection device 600 can be placed on or removed from the pipe 602 by one or more divers or using undersea equipment such as a remotely operated undersea vehicle as described in connection with FIG. 1.

The pipe inspection device 600 comprises a first jaw 610 and a second jaw 611 that engage opposing sides of the pipe 602 to secure the device onto the pipe. The first jaw 610 and the second jaw 611 are pivoting and can be opened and closed by operating a torque handle 629. The device has an inner surface or surfaces that form a generally curved shape which contacts the outer surface of the pipe 602. The device 600 includes a controller housing and one or more sensor housings. The controller housing encompasses a controller 641 that manages the operations of the device 600. As illustrated in FIG. 6B, the controller housing and the sensor housings can be compartments that are integrated into the device 600. The one or more sensor housings each includes an electromagnetic sensor.

The example device 600 has five sensor housings and each sensor housing includes an electromagnetic sensor, such as first sensor housing 630 comprising first sensor 631 and second sensor housing 650 comprising second sensor 651. In other embodiments, a fewer or greater number of sensors and sensor housings can be included in the pipe inspection device. The sensors can be spaced in various configurations about the pipe when the inspection device is attached to the pipe. FIG. 6B shows the inspection device 600 oriented with the controller at the 12 o'clock position. However, in other embodiments, the inspection device can be mounted to the pipe at other clock positions as needed to inspect various sections of the wall of the pipe. Additionally, in other embodiments, the inspection device can be configured with arrays of sensors extending axially along the central axis 603 of the pipe 602. Positioning an array of sensors that extend along the central axis 603 of the pipe 602 can assist with identifying sections of wear or defects that extend along the inner wall of the pipe 602 in a direction generally parallel to the central axis 603.

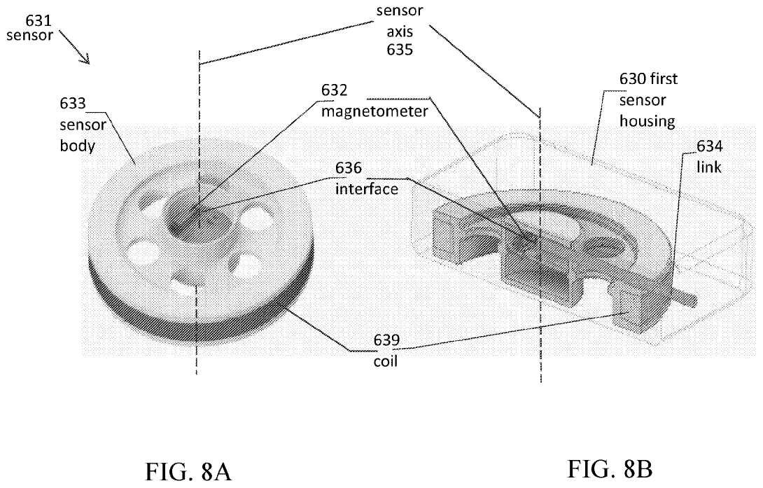

The details of the sensors will be discussed further in connection with FIGS. 8A and 8B. While the sensors can have a variety of configurations, the example sensors illustrated in FIGS. 6B, 8A, and 8B, are in the shape of a disc and are mounted in proximity to the inner surface of the device 600 to optimize the collection of magnetic field data from the wall of the pipe 602. In certain embodiments, the sensors can be arranged on the inspection device so that they come into direct contact with the pipe wall to optimize the collection of magnetic field data from the wall of the pipe. Each disc-shaped sensor has a sensor axis 635 about which the sensor is generally rotationally symmetric. Each disc-shaped sensor is oriented with the sensor axis 635 normal to the outer surface of the pipe 602 in order to direct a magnetic field generated by the coil 639 of the sensor into the wall of the pipe.

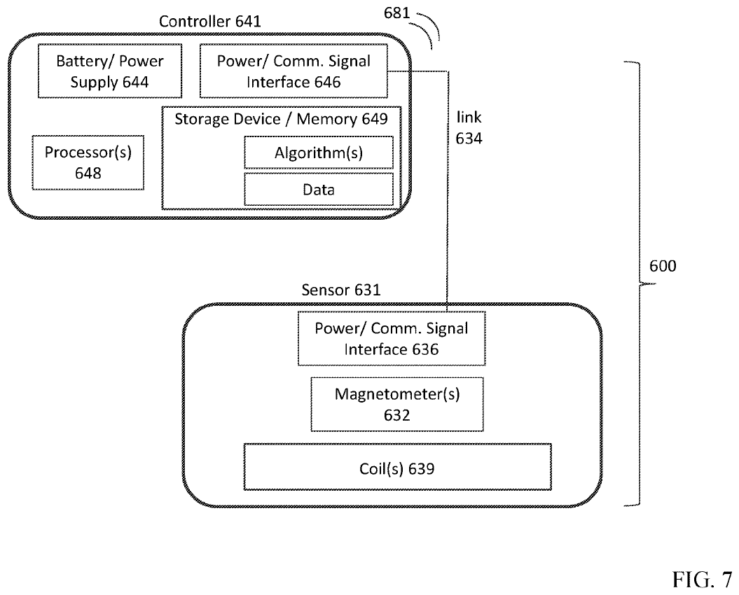

Referring now to FIG. 7, further details of the first sensor 631 and the controller 641 are illustrated. The controller 641 includes a power source 644, such as a battery. The power source 644 can include a power supply that modulates the power to deliver power and communication signals for the inspection device 600. The power and communication signals are provided via a controller signal interface 646 and a link 634 between the controller 641 and the sensors of the inspection device 600. The link can be wired or wireless, but in the example of device 600, wired links 634 pass through the device 600 to connect the controller and the sensors. The wired link 634 can be a single wire on which power and communication signals pass or it can represent multiple wires connecting the controller to the sensors. The controller signal interface 646 also can support a wireless link 681 for transmitting data between the controller 641 and a remote device such as a remotely operated vehicle or other equipment. The wireless link 681 can be an optical (e.g., via LED indicator 647), radio, acoustic, or magnetic communication link. The data transmitted via wireless link 681 can include magnetic field measurements, an indicator of pipe wall thickness, or control signals.

FIG. 7 also illustrates components of the first sensor 631. The other sensors of the pipe inspection device 600 can have similar components. The first sensor 631 can include a sensor signal interface 636 that sends and receives power and communication signals via link 634. Power signals received at sensor signal interface 636 from controller 641 can be used to power the one or more magnetometers 632 and the coil 639 of the sensor 631. A power signal to the coil 639 generates a magnetic field that is applied to the wall of the pipe 602 adjacent to the sensor 631. In response to the applied magnetic field, the wall of the pipe generates a response magnetic field that is measured by the magnetometer 632. Magnetic field measurements from the magnetometer 632 are communicated via sensor signal interface 636 and link 634 to the controller 641. A storage device 649 at the controller 641 can store the magnetic field measurements gathered from sensor 631 and other sensors of the device 600. A processor 648 can use algorithms stored in the storage device 649 to analyze the magnetic field measurements to generate an indicator or indicators of wall thickness. As examples, the indicator can be a wall thickness, a volume of material in the pipe wall, a change over time in wall thickness or the volume of pipe wall material, or an alert when pipe wall thickness or volume or change therein exceeds a predetermined threshold.

In yet another embodiment that is a variation of the arrangement illustrated in FIG. 7, the controller can be removed from the inspection device and can be included in a separate device, such a ROV or AUV that passes in proximity to the sensors on the pipe inspection device. When the ROV or AUV passes in proximity to the sensors on the pipe inspection device that is mounted on a pipe, the controller can collect the measured magnetic data via wireless signals (e.g., radio, optical, or acoustic signals) from the sensors. In yet another variation of this embodiment, the controller also can supply power to the sensors, e.g., via an induction coil, to power the coil and magnetometer of the sensor and to collect the magnetic measurement data.

FIGS. 8A and 8B illustrate further details of example first sensor 631. The sensor 631 includes a sensor body 633 in the shape of a disc with a sensor axis 635 passing through the center of the disc about which the sensor is generally rotationally symmetric. The perimeter of the sensor body 633 comprises a recess in which coil 639 is located. As explained previously, coil 639 receives power signals via link 634 from the power source 644 of the controller 641 and generates a magnetic field that is applied to the pipe wall adjacent to the sensor. The center portion of the sensor body 633 includes a circuit board on which is mounted the sensor signal interface 636 and the magnetometer 632. The magnetometer can be a MEMs device, such as a triaxial anisotropic magnetic resonance (AMR) sensor, or other types of magnetometers as are known to those in the field. In some embodiments, multiple magnetometers can be located in the sensor. Optionally, a counteracting coil can surround the magnetometer 632 to counteract the magnetic field generated by the applied magnetic field from coil 639 so that the magnetometer can obtain more accurate measurements of the response magnetic field generated by the pipe wall reacting to the applied magnetic field from coil 639.

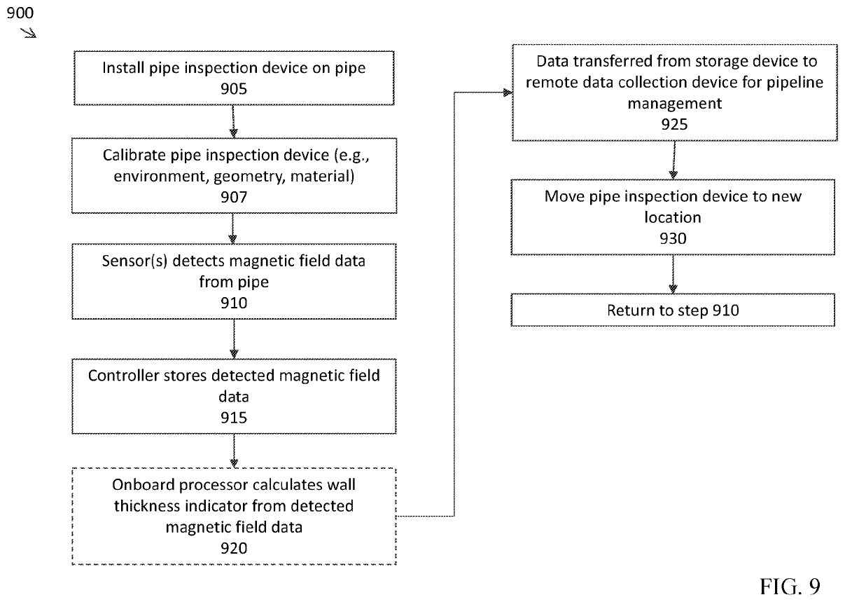

FIG. 9 illustrates an example method 900 for implementing a pipe inspection device, such as one of the previously described pipe inspection devices, for inspection and/or monitoring of a pipe. Method 900 is a non-limiting example and in alternate embodiments certain operations of method 900 may be modified, combined, performed in parallel, or omitted.

Beginning with operation 905, a pipe inspection device is attached to a section of pipe. The pipe inspection device can be installed manually by one or more people or can be installed using a piece of equipment such as a remotely operated vehicle. The pipe inspection device can be a clamping type of device that has jaws that engage opposing sides of the pipeline. Alternatively, the pipe inspection device can be attached by other types of securing means or fasteners such as a strap or a magnetic or adhesive device.

In operation 907, the pipe inspection device can be powered on and calibrated. In calibrating the device, one or more adjustments can be made based upon various factors to improve the operation of the inspection device. As one example, magnetic fields in the environment such as the Earth's magnetic field and any remnant field in the metal of the pipe can be measured passively by the magnetometer and used to adjust the subsequent measurements when the sensor applies a magnetic field to the pipe. Thermal measurements also can be gathered to calibrate the inspection device. The geometry of the pipe and any unique geometric characteristics in the cylindrical shape such as eccentricities is another factor that can be used to calibrate the inspection device. The type of material used in the pipe including its permeability to magnetic fields is yet another factor that can be included in calibrating the inspection device.

In operation 910, the sensor(s) of the inspection device detect magnetic field measurements from the pipe. These magnetic field measurements can be gathered over time and can be passive measurements or active measurements. With active measurements, a magnetic field is applied to the pipe using a power signal applied to a coil in the sensor and a magnetometer in the sensor measures the response magnetic field generated by the pipe in reaction to the applied magnetic field. The response magnetic field can provide evidence of a defect in the wall of the pipe, such as grooves or pitting caused by erosion or corrosion.

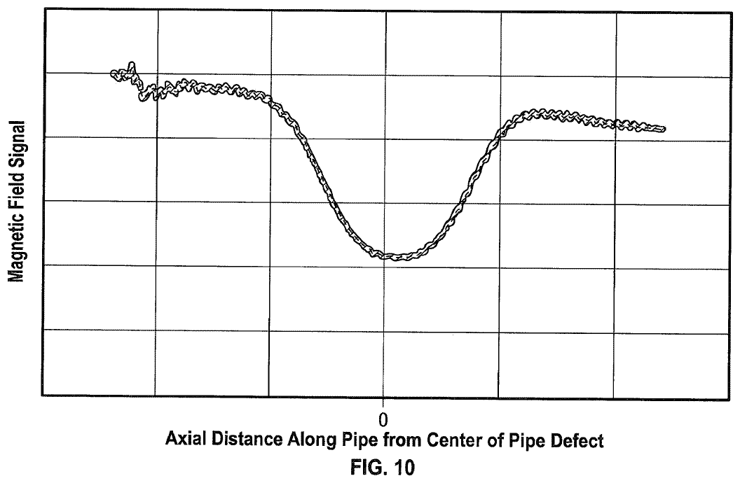

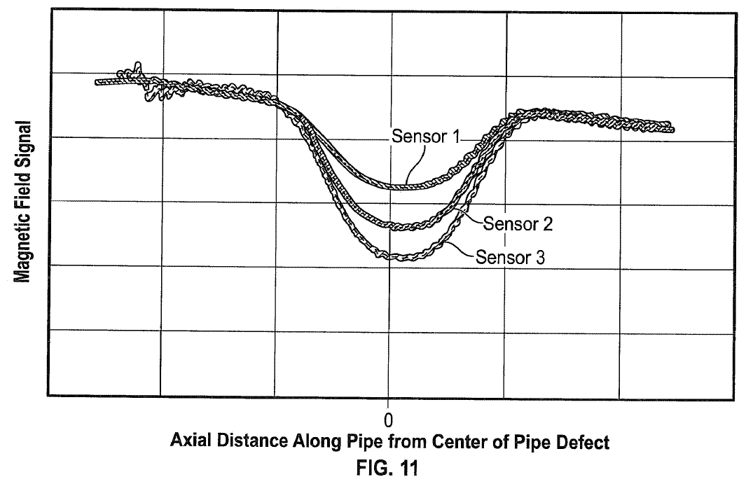

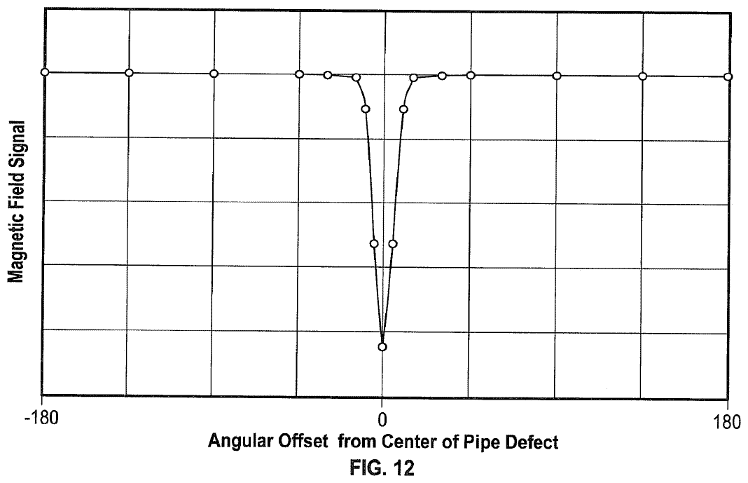

FIGS. 10, 11, and 12 provide illustrations of magnetic field signals, such as response magnetic field data, that can be measured by a magnetometer of the inspection device. FIG. 10 illustrates response magnetic field measurements reacting to an applied magnetic field that were collected along an axial length of an inspected pipe. The 0 position in the plot shown in FIG. 10 indicates the center of a defect that extends along the length of the pipe. The measurements show that as magnetic field signals are collected along the axial length of the pipe, there is a significant decrease in the magnetic field signal in the area immediately surrounding the 0 position at the center of the defect. The magnetic field signal increases as distance from the defect increases in each axial direction extending away from the center of the defect. FIG. 11 is similar to FIG. 10, but illustrates the change in the magnitude of the magnetic field signal as a function of changing the sensor. For example, sensor 2 may have more power than sensor 1, thereby increasing the applied magnetic field and generating a response magnetic field that reflects a greater change in the signal strength. Similarly, sensor 3 may have more power than sensor 2, thereby further increasing the applied magnetic field and generating a response magnetic field that reflects an even greater change in signal strength. FIG. 12 illustrates another example of magnetic field signals collected from an inspected pipe, but with the signals collected about a circumference of the pipe (in contrast the axial data shown in FIGS. 10 and 11). As suggested by the range of the data from −180 degrees to +180 degrees in FIG. 12, the sensors can wrap around the entire circumference of the pipe at a particular axial location along the length of the pipe. In the example data of FIG. 12, the inspection device was centered (the 0 position) at the center of the pipe wall defect and the magnetic field signal indicates a change in signal strength in the region proximate to the center of the defect in the pipe wall. If the inspection device is mounted at the 12 o'clock position as illustrated in FIGS. 6A and 6B, the data in FIG. 12 indicates a defect in the pipe wall at the top of the pipe with the defect disappearing at approximately −15 degrees and +15 degrees away from the 12 o'clock position at the top of the pipe.

In operation 915 of example method 900, the response magnetic field measurements are collected from the sensors and stored in the storage device of the controller. Optionally, in operation 920, the processor of the controller can analyze the collected response magnetic field data and determine a wall thickness indicator. The wall thickness indicator may be calculated by determining a correlation from the response magnetic field measurements to a percentage, a thickness, or a volume of material loss from the wall of the pipe. As other examples, the indicator can be a change over time in wall thickness or the volume of pipe wall material, or an alert when pipe wall thickness or volume or change therein exceeds a predetermined threshold. Alternatively, operation 920 can be omitted when the analysis of the data occurs remotely after the data is transferred from the pipe inspection device to a remote facility.

In operation 925, data is transferred from the storage device of the controller onboard the inspection device to a remote data collection device for pipeline management. The data can be transferred via wireless (e.g., optical, radio, acoustic, or magnetic) communication methods as previously referenced. In some embodiments, if the controller determines an amount of pipe wall material loss that exceeds a threshold, the controller can provide a warning indicator in the form of an optical and/or radio signal. The data transferred from the controller can be any type of magnetic field measurements and/or wall thickness indication data determined from analyzing the magnetic field measurements. Lastly, in operation 930, after the inspection and monitoring is completed a particular pipeline location, the pipe inspection device can be moved by personnel or by a remotely operated vehicle to a new location on the pipeline and the process can return to operation 910.

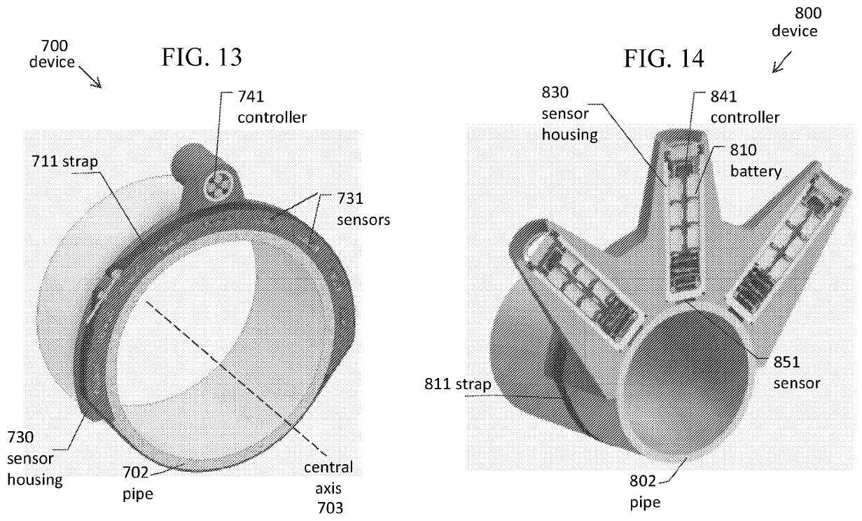

FIG. 13 illustrates an alternate embodiment of a pipe inspection device. Pipe inspection device 700 is similar in several respects to pipe inspection device 600 of FIGS. 6A and 6B, but with the following noted differences. Pipe inspection device 700 comprises a controller 741 similar to controller 641 that manages the operation of the device. The controller 741 is located in a controller housing portion of the device. The sensors 731 are located in a continuous sensor housing 730 of the device. Each of the sensors 731 is similar to the sensors of device 600 in that they comprise an electromagnetic coil for applying a magnetic field to the pipe wall and a magnetometer for measuring the response magnetic field from the reaction of the pipe wall to the applied magnetic field.

The inspection device 700 is shown attached to a pipe 702 having a central axis 703. The inner surface of the inspection device 700 is curved to fit securely to the outer wall of the pipe 702. In some embodiments, the sensor housing 730 can be flexible to accommodate different sizes of pipe. The device 700 is secured to the pipe 702 by a strap 711 that wraps around the device and around the circumference of the pipe 702. Accordingly, device 700 is attached and removed from the pipe in a different manner from the previously described clamping inspection devices.

FIG. 14 illustrates another example embodiment of a pipe inspection device. FIG. 14 shows a pipe 802 with device 800 secured thereto. Similar to the inspection device of FIG. 13, inspection device 800 is secured to the pipe 802 by a strap 811 that wraps around the device and the circumference of the pipe. Inspection device 800 differs from the previous example embodiments in that each sensor unit is a distinct, stand-alone unit with its own controller and power source. As illustrated in FIG. 14, each sensor unit comprises a sensor housing 830, a sensor 851, a battery 810, and a controller 841. The sensor units of device 800 are also unique in that each is positioned radially extending from the exterior surface of the pipe. The sensor 851 is located proximate the pipe wall to optimize the magnetic field measurements. Similar to the previous sensors, sensor 851 can include a coil used to apply a magnetic field to the pipe wall and a magnetometer that measures the response magnetic field of the pipe wall reacting to the applied magnetic field. Similar to the controller 641, controller 841 can include wired links for power and control signals as well as wireless links for communicating measured magnetic field data to a remote device or vehicle.

The magnetometer(s) used in the sensor housings described herein are commercially available devices. As one example, the magnetometer can be a micromechanical device with low power requirements that maximizes the life of the battery in the sensor housing. Similarly, the processor(s) described herein can be commercially available hardware processors such as an integrated circuit, a central processing unit, a multi-core processing chip, an SoC, a multi-chip module including multiple multi-core processing chips, or another hardware processor as known to those of skill in this field. The transmitters and receivers described herein can include signal transfer links that transmit and receive communications via known communication protocols. Lastly, the data storage devices described herein can be persistent storage devices, such as flash memory, that can store software instructions and data.

For any figure shown and described herein, one or more of the components may be omitted, added, repeated, and/or substituted. Additionally, it should be understood that in certain cases components of the example systems can be combined or can be separated into subcomponents. Accordingly, embodiments shown in a particular figure should not be considered limited to the specific arrangements of components shown in such figure. Further, if a component of a figure is described but not expressly shown or labeled in that figure, the label used for a corresponding component in another figure can be inferred to that component. Conversely, if a component in a figure is labeled but not described, the description for such component can be substantially the same as the description for the corresponding component in another figure.

With respect to the example methods described herein, it should be understood that in alternate embodiments, certain steps of the methods may be performed in a different order, may be performed in parallel, or may be omitted. Moreover, in alternate embodiments additional steps may be added to the example methods described herein. Accordingly, the example methods provided herein should be viewed as illustrative and not limiting of the disclosure.

Terms such as “first”, “second”, “top”, “bottom”, “side”, “distal”, “proximal”, and “within” are used merely to distinguish one component (or part of a component or state of a component) from another. Such terms are not meant to denote a preference or a particular orientation, and are not meant to limit the embodiments described herein. In the example embodiments described herein, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

The terms “a,” “an,” and “the” are intended to include plural alternatives, e.g., at least one. The terms “including”, “with”, and “having”, as used herein, are defined as comprising (i.e., open language), unless specified otherwise.

When Applicant discloses or claims a range of any type, Applicant's intent is to disclose or claim individually each possible number that such a range could reasonably encompass, including end points of the range as well as any sub-ranges and combinations of sub-ranges encompassed therein, unless otherwise specified. Numerical end points of ranges disclosed herein are approximate, unless excluded by proviso.

Values, ranges, or features may be expressed herein as “about”, from “about” one particular value, and/or to “about” another particular value. When such values, or ranges are expressed, other embodiments disclosed include the specific value recited, from the one particular value, and/or to the other particular value. Similarly, when values are expressed as approximations, by use of the antecedent “about,” it will be understood that the particular value forms another embodiment. It will be further understood that there are a number of values disclosed therein, and that each value is also herein disclosed as “about” that particular value in addition to the value itself. In another aspect, use of the term “about” means ±20% of the stated value, ±15% of the stated value, ±10% of the stated value, ±5% of the stated value, ±3% of the stated value, or ±1% of the stated value.

Although embodiments described herein are made with reference to example embodiments, it should be appreciated by those skilled in the art that various modifications are well within the scope of this disclosure. Those skilled in the art will appreciate that the example embodiments described herein are not limited to any specifically discussed application and that the embodiments described herein are illustrative and not restrictive. From the description of the example embodiments, equivalents of the elements shown therein will suggest themselves to those skilled in the art, and ways of constructing other embodiments using the present disclosure will suggest themselves to practitioners of the art. Therefore, the scope of the example embodiments is not limited herein.

What is claimed is:

1. A clamping inspection device for measuring a characteristic of a wall of a pipe, the clamping inspection device comprising:
a first jaw that engages a first side of the pipe;
a second jaw that engages a second side of the pipe;
a securing means for securing the first jaw and the second jaw to the pipe;
a sensor coupled to at least one of the first jaw and the second jaw, the sensor comprising a magnetometer that detects magnetic field measurements associated with the characteristic of the wall of the pipe; and
a controller coupled to the clamping inspection device, the controller comprising a power source and data storage device, wherein the data storage device receives the magnetic field measurements from the sensor via a communication link.

2. The clamping inspection device of claim 1, wherein the sensor further comprises a coil that receives a power signal from the power source and generates an applied magnetic field.

3. The clamping inspection device of claim 2, wherein the magnetic field measurements are response magnetic field measurements generated in response to the applied magnetic field.

4. The clamping inspection device of claim 1, wherein the controller further comprises a wireless communication link that transmits the magnetic field measurements to a remote data collection device, wherein the wireless communication link communicates the magnetic field measurements by one of optical signals, radio signals, acoustic signals, and magnetic pulse signals.

5. The clamping inspection device of claim 4, wherein the remote collection device is onboard one of: a remotely operated vehicle, an autonomous underwater vehicle, equipment located undersea, and a platform at a water's surface.

6. The clamping inspection device of claim 1, wherein the controller comprises a processor that analyzes the magnetic field measurements and determines a wall thickness indicator.

7. The clamping inspection device of claim 6, wherein the processor calibrates the clamping inspection device using at least one of environmental magnetic field measurements, a geometry of the pipe, and a magnetic permeability of material of the pipe.

8. The clamping inspection device of claim 1, wherein the magnetic field measurements associated with the characteristic of the wall of the pipe are compared to prior magnetic field measurements to determine a change in the characteristic of the wall of the pipe.

9. A method for measuring a characteristic of a wall of a pipe using a pipe inspection device, the method comprising:
installing the pipe inspection device at a first location on the pipe;
detecting, by a magnetometer, magnetic field measurements associated with the characteristic of the wall of the pipe, the magnetometer located within a sensor of the pipe inspection device; and
transmitting, by a controller via a wireless communication link, the magnetic field measurements to a remote data collection device.

10. The method of claim 9, wherein the magnetic field measurements are response magnetic field measurements generated in response to an applied magnetic field, the applied magnetic field generated by a coil of the sensor that receives a power signal from a power source of the controller.

11. The method of claim 9, wherein the wireless communication link transmits the magnetic field measurements by one of optical signals, radio signals, acoustic signals, and magnetic pulse signals.

12. The method of claim 9, wherein the remote data collection device is onboard one of: a remotely operated vehicle, an autonomous underwater vehicle, equipment located undersea, and a platform at the water's surface.

13. The method of claim 9, further comprising:
calculating, by a processor, a wall thickness indicator from the magnetic field measurements; and
transmitting, by the controller, the wall thickness indicator from the data storage device to the remote data collection device.

14. The method of claim 9, further comprising: calibrating the pipe inspection device using at least one of environmental magnetic field measurements, a geometry of the pipe, and a magnetic permeability of material of the pipe.

15. The method of claim 9, wherein the magnetic field measurements associated with the characteristic of the wall of the pipe are compared to prior magnetic field measurements to determine a change in the characteristic of the wall of the pipe.

16. The method of claim 9, further comprising:
disengaging, using a remotely operated vehicle, the pipe inspection device from the pipe at the first location;
installing the pipe inspection device at a second location on the pipe;
detecting, by the magnetometer, magnetic field measurements associated with the wall thickness of the pipe at the second location; and
transmitting, by the controller, the magnetic field measurements from the second location to the remote data collection device.

17. An inspection device for measuring a characteristic of a wall of a pipe, the inspection device comprising:
a fastener that secures the inspection device to the pipe;
a sensor comprising a magnetometer that detects magnetic field measurements associated with the characteristic of the wall of the pipe; and
a controller comprising a power source and a data storage device, wherein the data storage device receives the magnetic field measurements from the sensor via a communication link.

18. The inspection device of claim 17, wherein the fastener is one of: straps that wrap around the pipe, a magnet, an adhesive, or a clamp that engages opposing sides of the pipe.

19. The inspection device of claim 17, wherein the sensor further comprises a coil that receives a power signal from the power source and generates an applied magnetic field, and wherein the magnetic field measurements are response magnetic field measurements generated in response to the applied magnetic field.

20. The inspection device of claim 19, wherein the controller further comprises a wireless communication link that transmits the magnetic field measurements to a remote data collection device, wherein the wireless communication link communicates the magnetic field measurements by one of optical signals, radio signals, acoustic signals, and magnetic pulse signals.
